(19) United States
(12) Patent Application Publication
(10) Pub. No.: US 2011/0053045 A1
(43) Pub. Date: Mar. 3, 2011

(54) SOLID OXIDE FUEL CELL AND METHOD OF MANUFACTURING THE SAME

(76) Inventors: Sung Han KIM, Seoul (KR); Jae Hyuk Jang, Gyunggi-do (KR); Jong sik Yoon, Seoul (KR); Kyong Bok Min, Gyunggi-do (KR); Eon Soo Lee, Gyeongsangbuk-do (KR); Han Wool Ryu, Gyunggi-do (KR); Hong Ryul Lee, Gyunggi-do (KR); Jong Ho Chung, Gyunggi-do (KR); Jae Hyoung Gil, Seoul (KR)

(21) Appl. No.: 12/609,432

(22) Filed: Oct. 30, 2009

(30) Foreign Application Priority Data
Aug. 31, 2009 (KR) 10-2009-0081115
Sep. 10, 2009 (KR) 10-2009-0085543

(51) Int. Cl. H01M 8/10; B05D 5/12; C23C 14/34; H01M 4/04

(52) U.S. Cl. 429/497; 427/115; 204/192.17; 205/57; 427/446

(57) ABSTRACT

Disclosed is a solid oxide fuel cell, including a polygonal tubular support an outer surface of which has a plurality of planes, a plurality of unit cells respectively formed on the plurality of planes of the tubular support, inner connectors for connecting the plurality of unit cells in series, and a pair of outer connectors for connecting the plurality of unit cells connected in series to a current collector, so that respective unit cells are connected in series on the planes of the tubular support, thus exhibiting excellent cell performance and high power density per unit volume, and maintaining high voltage upon collection of current to thereby reduce power loss due to electrical resistance. A method of manufacturing the solid oxide fuel cell is also provided.

### CROSS REFERENCE TO RELATED APPLICATION

This application claims the benefit of Korean Patent Application No. 10-2009-0081115, filed Aug. 31, 2009, entitled “Solid oxide fuel cell and a method of manufacturing the same”, Korean Patent Application No. 10-2009-0085543, filed Sep. 10, 2009, entitled “Solid oxide fuel cell and a method of manufacturing the same”, which are hereby incorporated by reference in its entirety into this application.

### BACKGROUND OF THE INVENTION

1. Technical Field

The present invention relates to a solid oxide fuel cell (SOFC) and a method of manufacturing the same.

2. Description of the Related Art

A fuel cell is a device for directly converting the chemical energy of fuel (hydrogen, LNG, LPG, etc.) and air into electric power and heat using an electrochemical reaction. Unlike conventional techniques for generating power including combusting fuel, generating steam, driving a turbine and driving a power generator, the fuel cell neither undergoes a combustion procedure nor requires an operator and is thus regarded as a novel power generation technique which results in high cell performance without being accompanied by any concomitant environmental problems. The fuel cell discharges very small amounts of air pollutants such as SOx and NOx and also generates a small amount of carbon dioxide and is thus a pollution-free power generator, and is furthermore advantageous in terms of producing very little noise and not causing any vibrations.

The fuel cell includes for example a phosphoric acid fuel cell (PAFC), an alkaline fuel cell (AFC), a polymer electrolyte membrane fuel cell (PEMFC), a direct methanol fuel cell (DMFC), a solid oxide fuel cell (SOFC) and so on. In particular, the SOFC exhibits high power generation efficiency because of low overvoltage based on activation polarization and low irreversible loss. Furthermore, the SOFC is advantageous because various types of fuel, such as hydrogen, carbon and a hydrocarbon, may be used, and also because the reaction rate at the electrodes is high, thus obviating a need to use an expensive noble metal as an electrode catalyst. Moreover, the temperature of the heat generated during power generation is very high, and thus the heat is very usable. In addition, heat generated from the SOFC is used to reform fuel and may also be utilized as an energy source for industrial purposes or for air cooling in a cogeneration system. Hence, the SOFC is essential for realizing the hydrogen-based society of the future.

In accordance with the operating principle of the SOFC, the SOFC typically generates power through the oxidation of hydrogen or carbon monoxide, and the reactions at the anode and cathode are represented by Reaction 1 below.

Anode: H₂+O²⁻→H₂O+2e⁻

CO+O²⁻→CO₂+2e⁻

Cathode: O₂+4e⁻→2O²⁻

Overall Reaction: H₂+CO+O₂→H₂O+CO₂ Reaction 1

In the above reactions, electrons are delivered to the cathode through an external circuit, and simultaneously the oxygen ion generated at the cathode is transferred to the anode through an electrolyte. At the anode, hydrogen or carbon monoxide is combined with the oxygen ion, thus producing electrons and water or carbon dioxide.

FIGS. 1A and 1B are perspective views showing conventional SOFCs.

As shown in FIGS. 1A and 1B, examples of the SOFCs include a planar SOFC 10 and a tubular SOFC 20.

The planar SOFC 10 is configured such that a separator 11, a unit cell 13 and a separator 11 are sequentially layered. The planar SOFC 10 has superior cell performance, higher power density and a simpler manufacturing process compared to the tubular SOFC 20. In particular, the planar SOFC is advantageous because electrodes and an electrolyte are formed on a plane through tape casting, doctor blade coating, screen printing or the like, thus resulting in low manufacturing cost.

However, the planar SOFC 10 needs a large external manifold for supplying and discharging reactive gas, and also, the structure thereof is required to be subjected to to absolutely hermetic gas sealing. To this end, a sealing member 15 for gas sealing should be disposed between the separator 11 and the unit cell 13. However, the sealing member 15 has low durability at high temperature and may undesirably cause cracking. Furthermore, although a gas sealing process using mechanical compression, cement, glass and a combination of glass and cement is being developed, there still occur many problems. In the case of mechanical compression conducted for sealing purposes, a ceramic element may undergo non-uniform stress undesirably incurring cracking. In the case of cement or glass, it may react with a material for a fuel cell at high temperature, and thus may negatively affect the fuel cell.

On the other hand, the tubular SOFC 20 is configured such that an electrolyte 23 and an anode 25 are sequentially layered on the outer surface of a cathode support 21, and a connector 27 for connecting a unit cell to another unit cell is formed on the upper portion of the cathode support 21. The tubular SOFC 20 obviates a need for additional gas sealing and therefore exhibits long-term durability and is stable under thermal impact, unlike the planar SOFC 10.

However, when unit cells are connected and thus a bundle thereof is formed, they have a large volume, resulting in comparatively low performance and power density. Also, because the outer surface of the cathode support 21 is curved, it is difficult to uniformly apply the electrodes and electrolyte, compared to the planar SOFC 10.

### SUMMARY OF THE INVENTION

Accordingly, the present invention has been made keeping in mind the problems encountered in the related art and the present invention is intended to provide an SOFC having a polygonal tubular support the outer surface of which has a plurality of planes thus eliminating a need for gas sealing and exhibiting high cell performance and power density, to and also to provide a method of manufacturing the same.

An aspect of the present invention provides an SOFC, including a polygonal tubular support the outer surface of which has a plurality of planes, a plurality of unit cells respectively formed on the plurality of planes of the tubular support, inner connectors for connecting the plurality of unit cells in series, and a pair of outer connectors for connecting the plurality of unit cells connected in series to a current collector.

In this aspect, the plurality of unit cells may include a plurality of first electrodes respectively formed on the planes of the tubular support except for edges of the tubular support, a plurality of electrolytes formed on outer surfaces of the first electrodes, and a plurality of second electrodes formed on outer surfaces of the electrolytes.

In this aspect, the pair of outer connectors may be formed at both sides of a predetermined edge of the tubular support such that one of the pair of outer connectors is connected to one end of the first electrode and the other of the pair of outer connectors is connected to one end of the second electrode adjacent to the one end of the first electrode, so as to connect the one end of the first electrode and the one end of the second electrode to the current collector, and the inner connectors may be used so as to connect one end of the first electrode and one end of the second electrode adjacent to the one end of the first electrode, which are formed at both sides of each of remaining edges of the tubular support except for the predetermined edge of the tubular support, to each other, and the inner connectors may be gas impermeable.

In this aspect, in order to cover a lateral surface of the other end of each of the first electrodes, an end of each of the electrolytes corresponding thereto may extend toward the tubular support, and the one end of each of the second electrodes may extend toward the tubular support so that the extending end of each of the electrolytes is covered therewith.

In this aspect, each of the inner connectors is isolated from the other end of the second electrodes, and the one of the pair of outer connectors, which is connected to the to first electrode, is isolated from the other end of the second electrode.

In this aspect, each of the first electrodes may be an anode, and each of the second electrodes may be a cathode.

In this aspect, each of the first electrodes may be a cathode, and each of the second electrodes may be an anode.

In this aspect, the outer surface of the tubular support may have three, four, five or six planes.

In this aspect, the inner surface of the tubular support may be cylindrically curved.

In this aspect, the tubular support may be formed of an insulating material.

In this aspect, the tubular support may be formed of a porous material.

In this aspect, the tubular support may be formed of an alumina-based ceramic material.

In this aspect, the tubular support may include a metal support and an insulating layer applied on an entire surface of the metal support.

In this aspect, the edges of the tubular support may be subjected to rounding treatment.

Another aspect of the present invention provides a method of manufacturing an SOFC, including (A) preparing a polygonal tubular support the outer surface of which has a plurality of planes, (B) respectively forming a plurality of unit cells on the plurality of planes of the tubular support, and (C) providing inner connectors for connecting the plurality of unit cells in series and a pair of outer connectors for connecting the plurality of unit cells to a current collector.

In this aspect, (B) may include (B1) forming a plurality of first electrodes on respective planes of the tubular support except for edges of the tubular support, (B2) forming a plurality of electrolytes on outer surfaces of the first electrodes, and (B3) forming a plurality of second electrodes on outer surfaces of the electrolytes.

In this aspect, (C) may include providing the pair of outer connectors which are formed at both sides of a predetermined edge of the tubular support such that one of the pair of outer connectors is connected to one end of the first electrode and the other of the pair of outer connectors is connected to one end of the second electrode adjacent to the one end of the first electrode, so as to connect the one end of the first electrode and the one end of the second electrode to the current collector, and providing the inner connectors so as to connect one end of the first electrode and one end of the second electrode adjacent to the one end of the first electrode, which are formed at both sides of each of remaining edges of the tubular support except for the predetermined edge of the tubular support, to each other.

In this aspect, forming the plurality of unit cells in (B) may be performed through tape casting, spray coating, dip coating, screen printing, doctor blade coating, electrochemical deposition, sputtering, ion beam sputtering, ion implantation, or plasma spraying.

In this aspect, each of the first electrodes may be an anode, and each of the second electrodes may be a cathode.

In this aspect, each of the first electrodes may be a cathode, and each of the second electrodes is an anode.

### BRIEF DESCRIPTION OF THE DRAWINGS

The features and advantages of the present invention will be more clearly understood from the following detailed description taken in conjunction with the accompanying drawings, in which:

FIGS. 1A and 1B are perspective views showing conventional SOFCs;

FIGS. 2 to 6 are perspective views sequentially showing a process of manufacturing an SOFC according to an embodiment of the present invention;

FIG. 7 is an enlarged view showing main parts of the SOFC according to the embodiment of the present invention;

FIGS. 8 to 10 are perspective views showing SOFCs according to modifications of the embodiment of the present invention;

FIGS. 11 to 14 are perspective views showing SOFCs according to another embodiment of the present invention and modifications thereof; and

FIG. 15 is a perspective view showing an SOFC according to a further embodiment of the present invention.

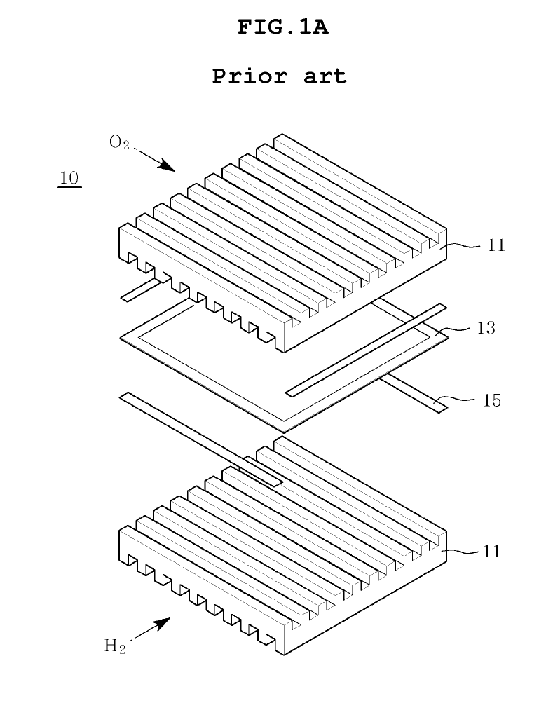

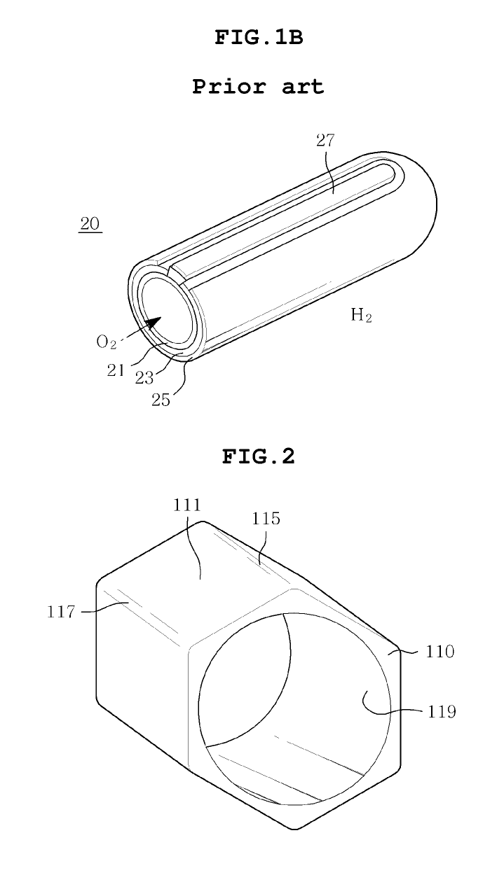

### DESCRIPTION OF SPECIFIC EMBODIMENTS

Hereinafter, a detailed description will be given of embodiments of the present invention with reference to the accompanying drawings. Throughout the drawings, the same reference numerals refer to the same or similar elements, and redundant descriptions are omitted. Also in the drawings, O₂ and H₂ are used merely for purposes of illustration to specify the operative procedure of a fuel cell but the type of gas supplied to an anode or a cathode is not restricted. In the description, the terms “one end”, “the other end”, “the lateral surface of the other end”, “one edge”, “first”, “second”, “outer” and so on are used only to distinguish one element from another element, and the elements are not defined by the above terms. Also in the description, in the case where known techniques pertaining to the present invention are regarded as unnecessary because they would make the characteristics of the invention unclear and also for the sake of description, the detailed descriptions thereof may be omitted.

Furthermore, the terms and words used in the present specification and claims should not be interpreted as being limited to typical meanings or dictionary definitions, but should be interpreted as having meanings and concepts relevant to the technical scope of the present invention based on the rule according to which an inventor can appropriately to define the concept implied by the term to best describe the method he or she knows for carrying out the invention.

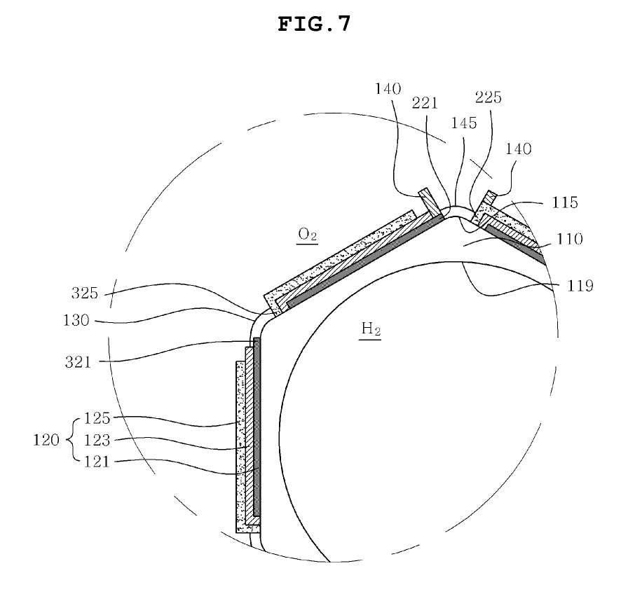

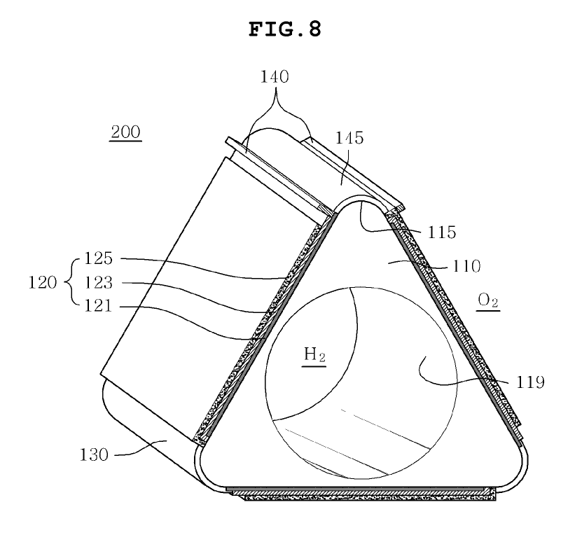

FIG. 6 is a perspective view showing an SOFC according to an embodiment of the present invention, FIG. 7 is an enlarged view showing main parts of the SOFC according to the embodiment of the present invention, and FIGS. 8 to 10 are perspective views showing SOFCs according to modifications of the embodiment of the present invention.

As shown in FIGS. 6 to 10, the SOFC according to the embodiment of the present invention includes a polygonal tubular support 110 the outer surface of which has a plurality of planes, a plurality of unit cells 120 respectively formed on the plurality of planes, inner connectors 130 for connecting the plurality of unit cells 120 in series, and a pair of outer connectors 140 for connecting the plurality of unit cells 120 connected in series to a current collector.

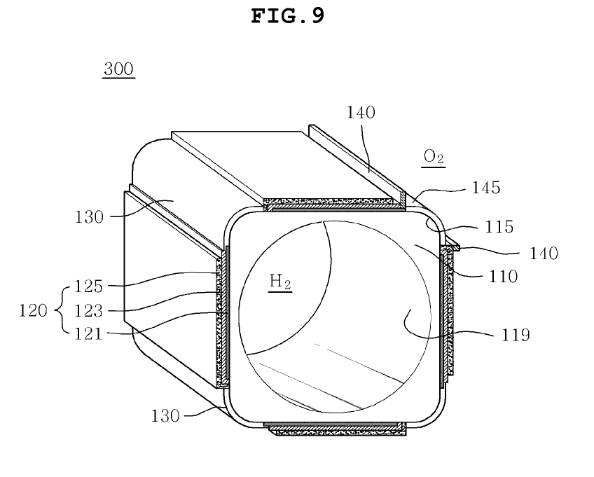

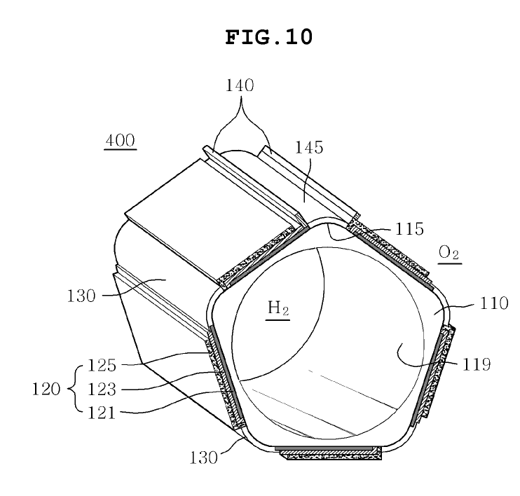

As shown in FIGS. 6, 8, 9 and 10, the SOFC according to the present invention may be provided in various forms. FIG. 6 illustrates an SOFC 100 using a hexagonal tubular support, FIG. 8 illustrates an SOFC 200 using a triangular tubular support, FIG. 9 illustrates an SOFC 300 using a rectangular tubular support, and FIG. 10 illustrates an SOFC 400 using a pentagonal tubular support. In this way, the SOFC may be manufactured in various forms depending on the shape of the tubular support 110.

The outer surface of the tubular support 110 may have three (FIG. 8), four (FIG. 9), five (FIG. 10) or six (FIG. 6) planes. This number of planes is merely illustrative and the number (N) of planes may fall within the entire natural number range from 3 to less than infinity (3≦N<∞). In the SOFC, because the number of unit cells 20 connected in series may be governed by the number (N) of planes, the number (N) of planes may be set in consideration of the magnitude of the necessary voltage. Also, inner connectors 130 are provided at respective edges between neighboring planes among the plurality of planes. In order to prevent the cracking of the inner connectors 130, the edges of the tubular support to may be subjected to rounding treatment.

A gas (which is fuel in the present embodiment) should be supplied to the inside of the tubular support 110. Thus, in order to increase bonding reliability between the tubular support and a manifold serving as a gas supplier and prevent the leakage of gas from the bonded portion therebetween, the inner surface 119 of the tubular support 110 may be cylindrically curved. Moreover, the tubular support 110 should transfer the supplied gas (which is fuel in the present embodiment) to first electrodes (which are anodes 121 in the present embodiment), and thus may be formed of a porous material.

Also, the plurality of unit cells 120 is connected in series on the plurality of planes. Hence, in order to prevent the shorting of current at respective unit cells 120, the tubular support 110 may be formed of an insulating material. The tubular support 110 may be formed using a typical ceramic material including yttria-stabilized zirconia (YSZ), in particular, using an alumina (Al₂O₃)-based ceramic material which is comparatively inexpensive, thus ensuring price competitiveness.

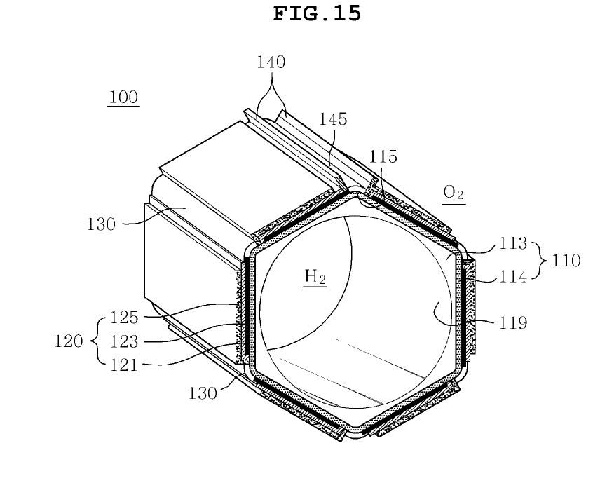

As shown in FIG. 15, the tubular support 110 may include a metal support 113 and an insulating layer 114 applied on the entire surface of the metal support 113. As such, the metal support 113 functions to support the fuel cell, and the insulating layer 114 plays a role in preventing the shorting of current from happening at any of the plurality of unit cells 120 connected in series.

The type of metal support 113 is not necessarily limited. Taking into consideration the properties of the SOFC operating at high temperature, particularly useful is stainless steel having high thermal oxidation resistance and heat resistance. Also, because the gas (which is fuel in the present invention) supplied from the manifold should be transferred to the first electrodes (which are anodes 121 in the present embodiment), the support may be formed of a porous material.

The insulating layer 114 may be made of porous zirconia or porous alumina able to transfer the gas to the first electrodes while performing its intrinsic insulation function.

The tubular support 110, including the metal support 113 and the insulating layer 114, is inexpensive and may exhibit superior properties in terms of thermal expansion and thermal impact, compared to a ceramic support.

In the present embodiment, a first electrode is determined to be an anode 121, and a second electrode is determined to be a cathode 125, and thus, a unit cell 120 including these electrodes is specified below.

A unit cell 120 which is a basic unit for producing electrical energy includes an anode 121, an electrolyte 123, and a cathode 125. As mentioned above, the outer surface of the tubular support 110 has a plurality of planes, and thus a plurality of unit cells 120 is formed on the plurality of planes. Therefore, the SOFC according to the present invention is configured such that unit cells 120 are not integrally formed on the outer surface of the support but are independently formed on respective planes 111 of the tubular support 110, unlike conventional SOFCs.

The formation of the unit cells is described below. Specifically, a plurality of anodes 121 is formed on respective planes of the tubular support 110 except for edges of the tubular support 110, and a plurality of electrolytes 123 is formed on outer surfaces of the anodes 121. Furthermore, a plurality of cathodes 125 is formed on outer surfaces of the electrolytes 123. The anodes 121 receive fuel from the tubular support 110, and the cathodes 125 receive air from the outside of the fuel cell, thus producing electrical energy.

The electrolytes 123 are formed to be considerably dense and gas impermeable, thus preventing fuel which is transferred from the inside of the tubular support 110 to the anodes 121 from leaking to the outside. Also, inner connectors 130 which will be described below are provided at edges of the tubular support where the electrolytes 123 are not formed, thus preventing the leakage of gas.

The inner connectors 130 function to connect the plurality of unit cells 120 formed to on the tubular support 110 in series, and the pair of outer connectors 140 function to connect the plurality of unit cells 120 connected in series to a current collector. In the SOFC according to the present invention, the plurality of unit cells 120 is formed on a single tubular support 110, unlike the conventional SOFCs. Thus, the inner connectors 130 are used to connect the plurality of unit cells 120 in series, and the pair of outer connectors 140 are used to connect the plurality of unit cells 120, which are connected in series by means of the inner connectors, to an external current collector.

The outer connectors 140 and the inner connectors 130 are specified with reference to FIG. 7. As is apparent from this drawing, the pair of outer connectors 140 are electrically connected to one end 221 of the anode and the other end 225 of the cathode, which are formed at both sides of a certain edge 115 of the tubular support 110. The pair of outer connectors 140 may be provided in the form of a protrusion for the sake of connection to the current collector, but the present invention is not limited thereto. Considering the shape of a fuel cell bundle, the pair of outer connectors may be provided in various forms. As such, in the case where the outer connector 140 connected to one end 221 of the anode comes into contact with one end of the cathode 125, a short may occur. Thus, it is desirable to space one end of the cathode 125 apart from the outer connector 140.

The inner connectors 130 are used so that one end 321 of the anode and the other end 325 of the cathode, which are formed at both sides of each of the remaining edges of the tubular support except for the edge 115 of the tubular support at which the pair of outer connectors 140 are formed, are electrically connected to each other. Specifically, the inner connectors 130 are formed at the remaining edges of the tubular support except for the edge 115 of the tubular support, whereby the plurality of unit cells 120 is connected in series. As such, in the case where the inner connector 130 connected to one end 321 of the anode comes into contact with one end of the cathode 125, a short may occur. Thus, it to may be desired to space one end of the cathode 125 apart from the inner connector 130.

Also, in the case where the inner connector 130 connected to the other end 325 of the cathode comes into contact with the other end of the anode 121, a short may occur. Therefore, the other end of the electrolyte 123 extends toward the tubular support 110 so that the lateral surface of the other end of the anode 121 is covered therewith, thus preventing contact between the inner connector 130 and the other end of the anode 121. Furthermore, the other end 325 of the cathode extends toward the tubular support 110, so that the extending other end of the electrolyte 123 is covered therewith, thereby enhancing reliability of the electrical connection between the inner connector 130 and the other end 325 of the cathode.

Because the inner connectors 130 and the outer connectors 140 are an electrical connection means, they should be undoubtedly made of an electrically conductive material. Also, the inner connectors 130 should be gas impermeable in order to prevent the fuel supplied from the inside of the tubular support 110 to the anodes 121 from leaking from the edges of the tubular support. Moreover, in order to prevent the leakage of gas from the edge 115 of the tubular support where the inner connector 130 is not formed, an additional gas impermeable material 145 may be applied on the edge 115 of the tubular support.

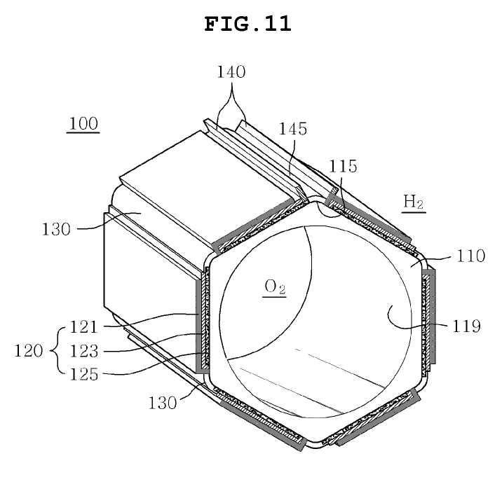

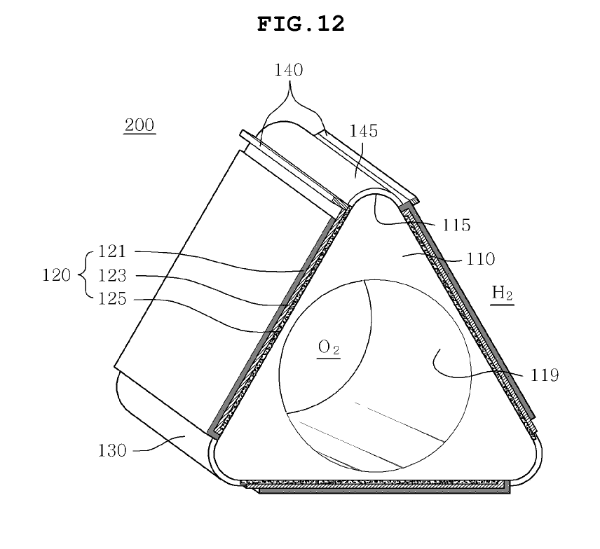

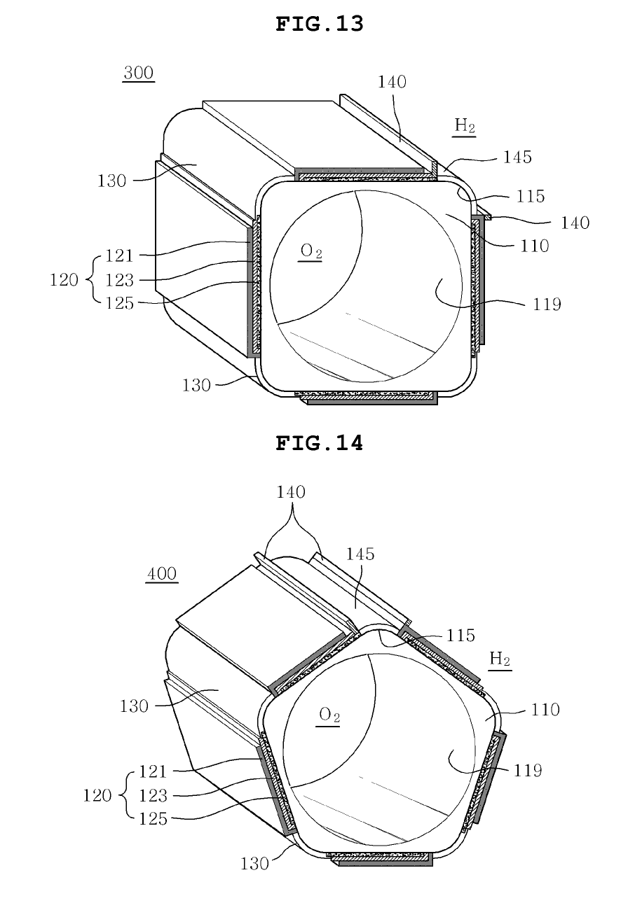

FIGS. 11 to 14 are perspective views showing SOFCs according to another embodiment of the present invention and modifications thereof.

The major difference between the present embodiment and the previous embodiment is the position at which the anode 121 and the cathode 125 are formed. Specifically, in the present embodiment, a first electrode 125 is determined to be a cathode 125, and a second electrode is determined to be an anode 121. Below, the description the same as that of the previous embodiment is omitted, and portions of the description which are different are provided.

A plurality of cathodes 125 is formed on respective planes of a tubular support 110 except for the edges of the tubular support 110, and a plurality of electrolytes 123 is formed on outer surfaces of the cathodes 125. Also, a plurality of anodes 121 is formed on outer surfaces of the electrolytes 123. The cathodes 125 receive air from the tubular support 110, and the anodes 121 receive fuel from the outside of the fuel cell, thus producing electrical energy. The tubular support 110 may be formed of a porous material.

A pair of outer connectors 140 are electrically connected to one end of the cathode 125 and the other end of the anode 121, which are formed at both sides of a certain edge 115 of the tubular support 110. In the case where the outer connector 140 connected to one end of the cathode 125 comes into contact with one end of the anode 121, a short may occur. Thus, it may be desired to space one end of the anode 121 apart from the outer connector 140.

Furthermore, inner connectors 130 are used so that one end of the cathode 125 and the other end of the anode 121, which are formed at both sides of each of the remaining edges of the tubular support except for the edge 115 of the tubular support where the pair of outer connectors 140 are formed, are electrically connected to each other. As such, in the case where the inner connector 130 connected to one end of the cathode 125 comes into contact with one end of the anode 121, a short may occur. Thus, it may be desired to space one end of the anode 121 apart from the inner connector 130.

Also, in the case where the inner connector 130 connected to the other end of the anode 121 comes into contact with the other end of the cathode 125, a short may occur. Therefore, the other end of the electrolyte 123 extends toward the tubular support 110 so that the lateral surface of the other end of the cathode 125 is covered therewith, thus preventing the contact between the inner connector 130 and the other end of the cathode 125. Furthermore, the other end of the anode 121 extends toward the tubular support 110, so that the extending other end of the electrolyte 123 is covered therewith, thereby enhancing reliability of the electrical connection between the inner connector 130 and the other end of the anode 121.

The inner connectors 130 should be gas impermeable in order to prevent the air supplied from the inside of the tubular support 110 to the cathodes 125 from leaking from the edges of the tubular support. In order to prevent the leakage of gas from the edge 115 of the tubular support at which the inner connector 130 is not formed, an additional gas impermeable material 145 may be applied on the edge 115 of the tubular support.

Unlike conventional SOFCs, in the SOFC according to the present invention, a plurality of unit cells 120 is formed on a single tubular support 110, and is connected in series, thus producing electrical energy. Thereby, power density per unit volume may be increased, and high voltage may be maintained upon collection of current, thus reducing power loss due to electrical resistance. For example, in the case of the tubular support 110 the outer surface of which has six planes (FIGS. 6 and 11), when respective unit cells 120 may maintain an ideal voltage of 1.1 V, the SOFC according to the present invention may produce electrical energy having a voltage of 6.6 V. Hence, the SOFC according to the present invention may produce voltage six times as high as that of the conventional SOFCs under the same conditions, thus reducing power loss due to electrical resistance.

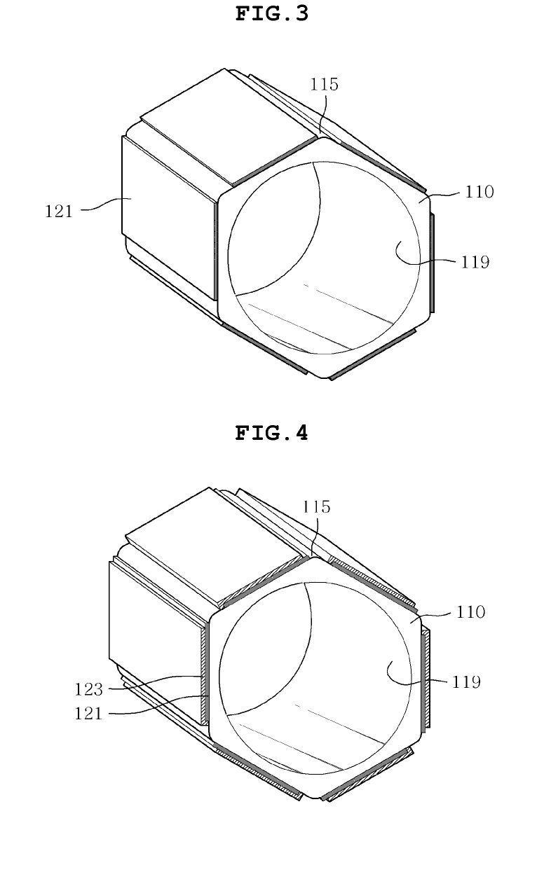

FIGS. 2 to 6 sequentially show the process of manufacturing the SOFC according to the embodiment of the present invention.

In this embodiment, a first electrode is determined to be an anode 121, and a second electrode is determined to be a cathode 125, but the scope of the present invention is not limited thereto. Even in the case where a first electrode is a cathode 125 and a second electrode is an anode 121, a unit cell 120 may be formed in the same manner, which will also be incorporated within the scope of the present invention.

As shown in FIGS. 2 to 6, the method of manufacturing the SOFC according to the present embodiment includes preparing a polygonal tubular support 110 the outer surface of which has a plurality of planes 111, respectively forming a plurality of unit cells 120 on the plurality of planes 111, and providing inner connectors 130 for connecting the plurality of unit cells 120 in series and a pair of outer connectors 140 for connecting the plurality of unit cells to a current collector.

As shown in FIG. 2, the polygonal tubular support 110 the outer surface of which has a plurality of planes 111 is prepared. The edges of the tubular support 110 are provided with inner connectors 130 in a subsequent procedure, and may be subjected to rounding treatment 117 in order to prevent cracking of the inner connectors 130. As mentioned above, the tubular support 110 may be formed of a material having insulating properties so as to prevent the shorting of current and being porous so as to transfer fuel to anodes 121.

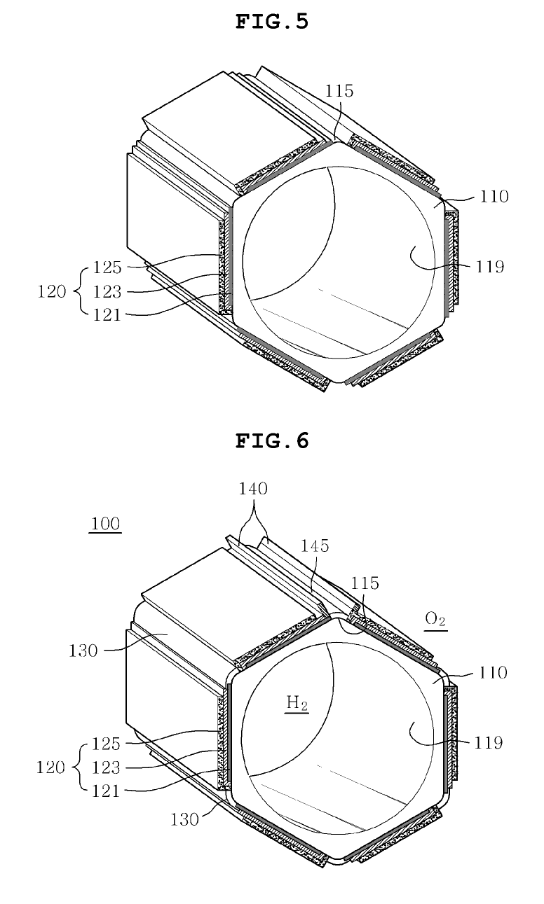

Next, as shown in FIGS. 3 to 5, the plurality of unit cells 120 is respectively formed on the plurality of planes 111. This procedure includes forming anodes 121 (FIG. 3), forming electrolytes 123 (FIG. 4) and forming cathodes 125 (FIG. 5).

Specifically, as seen in FIG. 3, the anodes 121 are formed on respective planes 111 of the tubular support 110 except for the edges of the tubular support 110. As such, it should be noted that the anodes 121 formed on respective planes 111 are not in contact with each other.

The anodes 121 may be made of a material (nickel/YSZ cermet) obtained by sintering nickel oxide powder containing 40˜60% zirconia powder. As such, nickel oxide is reduced to metal nickel by means of hydrogen upon production of electrical energy, thus exhibiting electronic conductivity.

Next, as shown in FIG. 4, the electrolytes 123 are formed on outer surfaces of the anodes 121. In order to prevent a short from occurring as a result of the inner connector 130 to be connected to the other end of the cathode 125 in a subsequent procedure coming into contact with the other end of the anode 121, the other end of each of the electrolytes 123 extends toward the tubular support 110 so that the lateral surface of the other end of each of the anodes 121 is covered therewith.

The electrolytes 123 function to prevent the gas (fuel or air) supplied from the inside of the tubular support 110 to the anodes 121 from leaking to the outside, and should not have small clearances, pores or scratches. The electrolytes 123 may be made of yttria-stabilized zirconia (YSZ) in which zirconia (ZrO₂) is doped with about 3˜10% of yttria (Y₂O₃). As such, YSZ, in which part of tetravalent zirconium ions is substituted by trivalent yttrium ions which is thus accompanied by the formation of one oxygen ion vacancy per two yttrium ions, allows the migration of oxygen ions via oxygen ion vacancies at high temperature.

Next, as shown in FIG. 5, the cathodes 125 are formed on outer surfaces of the electrolytes 123. As such, in order to enhance reliability of the electrical connection between the other end of the cathode 125 and the inner connector 130 in a subsequent procedure, the other end of each of the cathodes 125 extends toward the tubular support 110 and thus covers the other end of each of the electrolytes 123. Also, in order to prevent the shorting of current, it may be desired to space one end of the cathode 125 apart from the inner connector 130 which is to be connected to one end of the anode 121.

The cathodes 125 may be made of a Perovskite type oxide. Particularly useful is lanthanum strontium manganite (La_{0.84}Sr_{0.16})MnO₃ having high electronic conductivity. At the cathodes 125, LaMnO₃ converts oxygen into oxygen ions, which are then delivered to the anodes 121.

In the case where the first electrode is determined to be a cathode 125 and the second electrode is determined to be a anode 121, the positions where the anode 121 and the cathode 125 are formed may be reversed.

The process of forming the anodes 121, the cathodes 125 and the electrolytes 123 includes a dry process and a wet process. The dry process may include for example plasma spraying, electrochemical deposition, sputtering, ion beam sputtering, ion implantation, etc., and the wet process may include for example tape casting, spray coating, dip coating, screen printing, doctor blade coating, etc. In the present invention, when the anodes 121, the cathodes 125 and the electrolytes 123 are formed, in consideration of precision and economic efficiency, any one or a combination of two or more selected from among the above-stated processes may be used. For example, when the electrolytes 123 are formed, an adhesive mask is applied on the edges of the tubular support 110, dip coating is performed, and the adhesive mask is removed, thereby forming the electrolytes 123 on outer surfaces of the anodes 121 or cathodes 125 except for the edges of the tubular support. When unit cells having the cathodes 125, the electrolytes 123 and the anodes 121 formed in sequential order are manufactured, a plasma spraying process may be adopted to precisely form the anodes 121 while preventing the deformation of the cathodes 125.

Next, as shown in FIG. 6, the inner connectors 130 for connecting the plurality of unit cells 120 in series and the pair of outer connectors 140 for connecting the plurality of unit cells 120 to a current collector are provided. Specifically, the pair of outer connectors 140 are provided so that one end of the anode 121 and the other end of the cathode 125, which are formed at both sides of the edge 115 of the tubular support 110, are connected to the current collector, and the inner connectors 130 are provided so that one end of the anode 121 and the other end of the cathode 125, which are formed at both sides of each of the remaining edges of the tubular support except for the edge 115 of the tubular support 110 at which the pair of outer connectors 140 are formed, are connected to each other. The inner connectors 130 should be gas impermeable so that fuel supplied from the inside of the tubular support 110 to the anodes 121 is prevented from leaking from the edges of the tubular support. Also, in order to prevent the leakage of gas from the edge 115 of the tubular support where the inner connector 130 is not formed, an additional gas to impermeable material 145 may be provided at the edge 115 of the tubular support.

As such, the positions of the anode 121 and the cathode 125 may be reversed as mentioned above. In the case where the outermost electrode is the cathode 125, the inner connectors 130 and the outer connectors 140 are exposed to an oxidizing atmosphere, and thus should be formed of an oxidation resistant material.

As described hereinbefore, the present invention provides an SOFC and a method of manufacturing the same. According to the present invention, the SOFC includes a polygonal tubular support, the outer surface of which has a plurality of planes, and a plurality of unit cells, which are respectively formed on the plurality of planes and are connected in series, thus exhibiting excellent cell performance and high power density per unit volume, and maintaining high voltage upon collection of current to thereby effectively reduce power loss due to electrical resistance.

Also, according to the present invention, the SOFC is advantageous because electrodes and an electrolyte are formed not on the curved surface but on the plane, and thus the manufacturing process thereof becomes simplified and the manufacturing cost thereof is decreased. Furthermore, the SOFC using the tubular support eliminates a need for gas sealing, and thus manifests high long-term durability and is stable under thermal impact.

Also, according to the present invention, the outer surface of the tubular support can be manufactured in various shapes, thereby effectively manufacturing an SOFC bundle having optimal power density per unit volume.

Also, according to the present invention, the tubular support can be formed of an alumina (Al₂O₃)-based ceramic material, thus ensuring price competitiveness compared to a conventional tubular support.

Also, according to the present invention, the tubular support can be manufactured by applying an insulating layer on the entire surface of a metal support, thus facilitating the to formation thereof and ensuring price competitiveness, compared to a conventional tubular support. The metal support can exhibit superior properties in terms of thermal expansion and thermal impact upon the on-off cycling operation of the SOFC, compared to a conventional ceramic support.

Although the embodiments of the present invention regarding the SOFC and the method of manufacturing the same have been disclosed for illustrative purposes, those skilled in the art will appreciate that various modifications, additions and substitutions are possible, without departing from the scope and spirit of the invention as disclosed in the accompanying claims. Accordingly, such modifications, additions and substitutions should also be understood as falling within the scope of the present invention.

What is claimed is:

1. A solid oxide fuel cell, comprising:
a polygonal tubular support an outer surface of which has a plurality of planes;
a plurality of unit cells respectively formed on the plurality of planes of the tubular support;
inner connectors for connecting the plurality of unit cells in series; and
a pair of outer connectors for connecting the plurality of unit cells connected in series to a current collector.

2. The solid oxide fuel cell as set forth in claim 1, wherein the plurality of unit cells comprises:
a plurality of first electrodes respectively formed on the planes of the tubular support except for edges of the tubular support;
a plurality of electrolytes formed on outer surfaces of the first electrodes; and
a plurality of second electrodes formed on outer surfaces of the electrolytes.

3. The solid oxide fuel cell as set forth in claim 2, wherein the pair of outer connectors are formed at both sides of a predetermined edge of the tubular support such that one of the pair of outer connectors is connected to one end of the first electrode and the other of the pair of outer connectors is connected to one end of the second electrode adjacent to the one end of the first electrode, so as to connect the one end of the first electrode and the one end of the second electrode to the current collector, and
the inner connectors are used so as to connect one end of the first electrode and one end of the second electrode adjacent to the one end of the first electrode, which are formed at both sides of each of remaining edges of the tubular support except for the predetermined edge of the tubular support, to each other, and the inner connectors are gas impermeable.

4. The solid oxide fuel cell as set forth in claim 3, wherein, in order to cover a lateral surface of the other end of each of the first electrodes, an end of each of the electrolytes corresponding thereto extends toward the tubular support, and
the one end of each of the second electrodes extends toward the tubular support so that the extending end of each of the electrolytes is covered therewith.

5. The solid oxide fuel cell as set forth in claim 3, wherein each of the inner to connectors is isolated from the other end of the second electrodes, and the one of the pair of outer connectors, which is connected to the first electrode, is isolated from the other end of the second electrode.

6. The solid oxide fuel cell as set forth in claim 2, wherein each of the first electrodes is an anode, and each of the second electrodes is a cathode.

7. The solid oxide fuel cell as set forth in claim 2, wherein each of the first electrodes is a cathode, and each of the second electrodes is an anode.

8. The solid oxide fuel cell as set forth in claim 1, wherein the outer surface of the tubular support has three, four, five or six planes.

9. The solid oxide fuel cell as set forth in claim 1, wherein an inner surface of the tubular support is cylindrically curved.

10. The solid oxide fuel cell as set forth in claim 1, wherein the tubular support is formed of an insulating material.

11. The solid oxide fuel cell as set forth in claim 1, wherein the tubular support is formed of a porous material.

12. The solid oxide fuel cell as set forth in claim 1, wherein the tubular support is formed of an alumina-based ceramic material.

13. The solid oxide fuel cell as set forth in claim 1, wherein the tubular support to comprises a metal support and an insulating layer applied on an entire surface of the metal support.

14. The solid oxide fuel cell as set forth in claim 1, wherein the edges of the tubular support are subjected to rounding treatment.

15. A method of manufacturing a solid oxide fuel cell, comprising:
(A) preparing a polygonal tubular support an outer surface of which has a plurality of planes;
(B) respectively forming a plurality of unit cells on the plurality of planes of the tubular support; and
(C) providing inner connectors for connecting the plurality of unit cells in series and a pair of outer connectors for connecting the plurality of unit cells to a current collector.

16. The method as set forth in claim 15, wherein (B) comprises:
(B1) forming a plurality of first electrodes on respective planes of the tubular support except for edges of the tubular support;
(B2) forming a plurality of electrolytes on outer surfaces of the first electrodes; and
(B3) forming a plurality of second electrodes on outer surfaces of the electrolytes.

17. The method as set forth in claim 16, wherein (C) comprises:
providing the pair of outer connectors which are formed at both sides of a predetermined edge of the tubular support such that one of the pair of outer connectors is connected to one end of the first electrode and the other of the pair of outer connectors is connected to one end of the second electrode adjacent to the one end of the first electrode, so as to connect the one end of the first electrode and the one end of the second electrode to the current collector, and
providing the inner connectors so as to connect one end of the first electrode and one end of the second electrode adjacent to the one end of the first electrode, which are formed at both sides of each of remaining edges of the tubular support except for the predetermined edge of the tubular support, to each other.

18. The method as set forth in claim 15, wherein the forming the plurality of unit cells in (B) is performed through tape casting, spray coating, dip coating, screen printing, doctor blade coating, electrochemical deposition, sputtering, ion beam sputtering, ion implantation, or plasma spraying.

19. The method as set forth in claim 16, wherein each of the first electrodes is an anode, and each of the second electrodes is a cathode.

20. The method as set forth in claim 16, wherein each of the first electrodes is a cathode, and each of the second electrodes is an anode.
